(19) United States
(12) Patent Application Publication
(10) Pub. No.: US 2026/0020322 A1
(43) Pub. Date: Jan. 15, 2026

(54) OPTIMIZATION OF BOTTOM ELECTRODE FOR THE ENHANCEMENT OF FERROELECTRIC PERFORMANCE IN HAFNIA-BASED OXIDE WITH BACK-END-OF-LINE (BEOL) COMPATIBLE PROCESS

(71) Applicant: VERSUM MATERIALS US, LLC, TEMPE, AZ (US)

(72) Inventors: NGUYEN MINH VU, BRANCHBURG, NJ (US); RAYMOND ANTHONY MECK, BRANCHBURG, NJ (US); JARED LEITH MCWILLIAMS, BRANCHBURG, NJ (US); NAVNIDHI KUMAR UPADHYAY, BRANCHBURG, NJ (US); MARIO LAUDATO, BRANCHBURG, NJ (US); CHARLENE CHEN, BRANCHBURG, NJ (US)

(21) Appl. No.: 18/994,573

(22) PCT Filed: Jul. 18, 2023
(86) PCT No.: PCT/US2023/070447

§ 371 Date: Jan. 14, 2025

Related U.S. Application Data
(60) Provisional application No. 63/368,891, filed on Jul. 20, 2022.

(51) Int. Cl. H10D 64/68; C23C 16/40; C23C 16/455; H10B 53/30; H10D 64/01

(52) U.S. Cl. CPC H10D 64/689; C23C 16/405; C23C 16/45531; C23C 16/45553; H10B 53/30; H10D 64/033

(57) ABSTRACT

The disclosed and claimed subject matter relates to a ferroelectric device having a bottom electrode, a film comprising crystalline ferroelectric materials that include a mixture of hafnium oxide and zirconium oxide having a substantial (i.e., approximately 40% or more) or majority portion of the material in a ferroelectric phase as deposited, a top electrode, and methods for preparing and depositing these materials. The bottom electrode is thin and has low roughness. The ferroelectric device is back-end-of-line (BEOL) compatible as all process steps take place at a temperature of 400 degrees Celsius or less.

### RELATED APPLICATIONS

This application claims priority to U.S. Provisional Patent application No. 63/368,891 filed on Jul. 20, 2022, which is hereby incorporated by reference.

### FIELD

The disclosed and claimed subject matter relates to ferroelectric materials deposited using vapor techniques, including atomic layer deposition (ALD). More specifically, the disclosed and claimed subject matter relates to ferroelectric devices having a bottom electrode comprising tungsten and a thin film crystalline ferroelectric materials that include a mixture of hafnium oxide and zirconium oxide having a substantial (i.e., approximately 40% or more) portion of the material in a ferroelectric phase and methods for preparing and depositing these materials. Significantly, these materials exhibit ferroelectric properties within the thermal budget for back end of line processes.

### BACKGROUND

Hafnium and zirconium oxide-based ferroelectric materials enable a variety of computing devices, including non-volatile memories and power-efficient logic devices, owing to their strong non-linear capacitance and remanent polarization. These materials may also be useful for a variety of other thermal and magnetic applications. Materials containing hafnium oxide and zirconium oxide are highly desirable for these applications owing to their compatibility with many CMOS fabrication processes and materials. They are also desirable owing to their ability to be deposited as thin films from the vapor phase, including by ALD processes involving the stepwise introduction and removal of a precursor followed by the introduction and removal of a reactant gas and other known processes (e.g., chemical vapor deposition (CVD) or pulsed CVD). Hafnium and zirconium oxide-based materials are polymorphic. Thus, their atoms can be arranged in several crystal structures (i.e., different ordered atomic arrangements). It is well known that the most stable bulk structure of hafnium and zirconium oxide-based materials is a monoclinic phase; however, this phase does not support ferroelectricity.

Other polymorphs (e.g., some orthorhombic and rhombohedral phases) have the symmetry required to support ferroelectric switching behavior, while still others (e.g., a tetragonal phase common in zirconium oxide thin films) can be anti-ferroelectric-like. The listing of related art attached hereto identifies reference materials describing these general features and aspects of the art in more detail.

In many vapor and atomic layer deposition processes for mixed hafnium oxide and zirconium oxide materials, the materials are amorphous as deposited

Even with thermal treatment, crystallization into monoclinic or other non-ferroelectric phases is common, and thereby reduces the fraction of the material capable of ferroelectric behavior. Several techniques have been developed to suppress the monoclinic phase in favor of phases that can support ferroelectricity. For example, incorporating other elements (including but not limited to Si, Al, Gd, La, and Y) into the material by sequential or concomitant introduction of precursors for the other elements into the vapor phase has been reported as a means of suppressing the monoclinic phase.

One study has shown that thick films (ca. 30 nm) of hafnium and zirconium oxide can demonstrate weak ferroelectricity from a ferroelectric phase. See Y. Li et al., “A Ferroelectric Thin Film Transistor Based on Annealing-Free HfZrO Film,” in IEEE Journal of the Electron Devices Society, vol. 5, no. 5, pp. 378-383, September 2017, doi: 10.1109/JEDS.2017.2732166. It appears that this behavior comes about due to the reduction of surface energy effects as compared to thinner films and the prolonged exposure to heat, which acts as a functional equivalent to annealing, in order to generate a film of such thickness. However, this study acknowledges what is generally known in the art: that thin films (ca. 20 nm or less) will not exhibit ferroelectric behavior absent annealing at elevated temperatures (either alone or combined with doping) and the capping approaches mentioned above.

Therefore, obtaining a desired ferroelectric phase traditionally depends on a complicated and complex combination of (i) the deposition conditions of the material itself, (ii) the choice of dopants, interfaces, importantly the top interface and (iii) thermal treatments after deposition. As can be easily appreciated, this combination of factors places significant limitations on the usefulness of such materials with respect to possible substrates, interlayers, electrodes, compositions, and processes. Indeed, the thermal profile in devices implementing such ferroelectric materials may not be compatible with all necessary or desirable applications for which ferroelectric materials may be useful. For example, it has been observed that specific electrodes may be needed to modulate electronic work functions, that interfaces may be needed to create barrier layers against chemical reactions and atomic diffusion, and that thermal processing conditions may be limited by stresses introduced in other layers in a multilayer stack.

Ferroelectric devices include ferroelectric tunnel junctions (FTJs) are two-terminal memory device where a ferroelectric material along with other interfacial dielectric material is sandwiched between two similar/dissimilar electrodes that stores the data based on the resistance switching of the device (i.e., low resistance and high resistance states indicate two distinct memory states and hence store one bit of information). The resistance change is initiated by the change in the tunneling barrier height between the two electrodes because of the switching of the orientation of permanent charge dipoles in the ferroelectric materials. Ferroelectric materials are typically crystalline/poly-crystalline materials that have permanent charge dipoles formed because of the asymmetry dipole charge centers inside the crystal lattice that are switchable by applying an electric field. Because of the permanent orientation switching of the dipoles, without an electric field such materials demonstrate a polarization (remnant polarization) that can change the direct tunnel barrier between the two electrodes.

Typically for an FTJ to work, an inherent asymmetry is needed between the two electrodes. This asymmetry can be achieved by two ways, (i) using two different types of contact materials for two electrodes (either two different metals or one metal and one semiconductor), (ii) using an interfacial dielectric material that is non-ferroelectric.

The basic idea of a Ferroelectric Tunnel Junction (FTJ) (called a polar switch at that time) may be attributed to Esaki et al. and was formulated in 1971. The FTJ has been extensively studied in literature in the last 10 years and several materials have been used such as Lead Zirconium Titanate —Pb(ZrₓTi₁₋ₓ)O₃(PZT), Bismuth Ferrite (BiFeO₃—BFO), Barium Titanate (BaTiO₃—BTO), Lanthanum Strontium Manganite (La_{0.67}Sr_{0.33}MnO₃-LSMO), organic polyvinylidene fluoride (PVDF) and organic Poly(Vinylidenefluoride-Trifluoroethylene)-P(VDF-TrFE). Due to poor BEOL process compatibility and integration complexity for these materials, hafnium oxide based FTJs have been recently deeply studied thanks to its good compatibility with CMOS process especially with certain dopant (Zr, Si) in order to improve ferroelectricity of the material. Use of interfacial layer (SiO₂, Al₂O₃, WOₓ) has been recently also introduced to introduce asymmetry within FTJ stack and increase the performance of the memory in terms of Tunneling Electro-resistance (TER) window and retention but still with results not sufficient to allow more than 2-3 memory level programming with acceptable retention for period longer than few hours.

### SUMMARY

In a first main aspect, a ferroelectric device is provided. The ferroelectric device comprising: a substrate; a first electrode and a second electrode, wherein the first electrode is disposed on the substrate; a thin film comprising crystalline material disposed between the first electrode and the second electrode, the crystalline material comprising hafnium oxide and zirconium oxide, wherein the crystalline material exhibits ferroelectric behavior as deposited; and wherein the first electrode comprises tungsten, titanium nitride, molybdenum, ruthenium, or combinations thereof, the thin film having a remnant polarization of greater than about 50 μC/cm².

In a further aspect of the first main aspect, the thin film is capable of exhibiting ferroelectric activity without a wakeup period. In a further aspect of the first main aspect, the second electrode comprises titanium nitride, tungsten, molybdenum, or combinations thereof. In a further aspect of the first main aspect, the first electrode has a thickness of between about 4 nm and about 50 nm. In a further aspect of the first main aspect, greater than 50% of the total volume of the first electrode is in a phase. In a further aspect of the first main aspect, the crystalline material comprises a hafnium oxide to zirconium oxide ratio of between about 1:3 and about 3:1. In a further aspect of the first main aspect, no process steps take place at a temperature greater than about 400 degrees Celsius.

In a further aspect of the first main aspect, the crystalline material is derived from one or more metallocene precursor having Formula I:

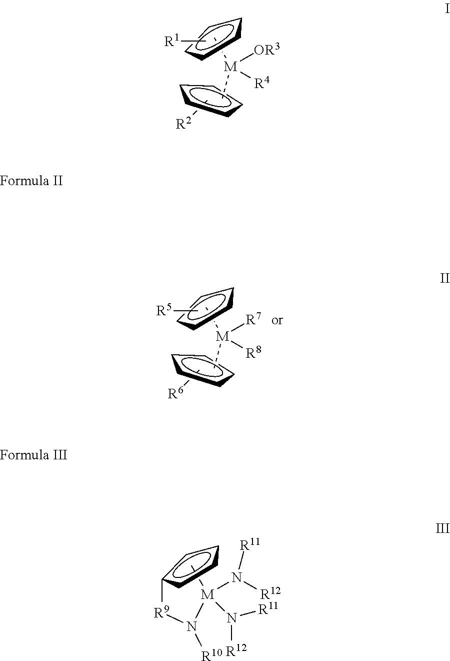

wherein (i) M is selected from Zr and Hf, (ii) R¹, R², R³, R⁴, R⁵, R⁶, R⁷ and R⁸ are each independently selected from a C₁-C₆ linear alkyl, a C₁-C₆ branched alkyl, a C₁-C₆ halogenated linear alkyl and a C₁-C₆ halogenated branched alkyl, (iii) R⁹ is a C₁-C₄ group selected from —CH₂CH₂—, —CH₂CH₂CH₂—, —CH(Me)CH₂—, —CH₂CH(Me)-, —CH₂CH₂CH₂—, —CHMeCH₂CH₂—, and (iv) R¹⁰, R¹¹, and R¹² are each independently a C₁-C₆ linear alkyl.

In a further aspect of the first main aspect, the crystalline material is derived from one or more metallocene precursor having Formula I:

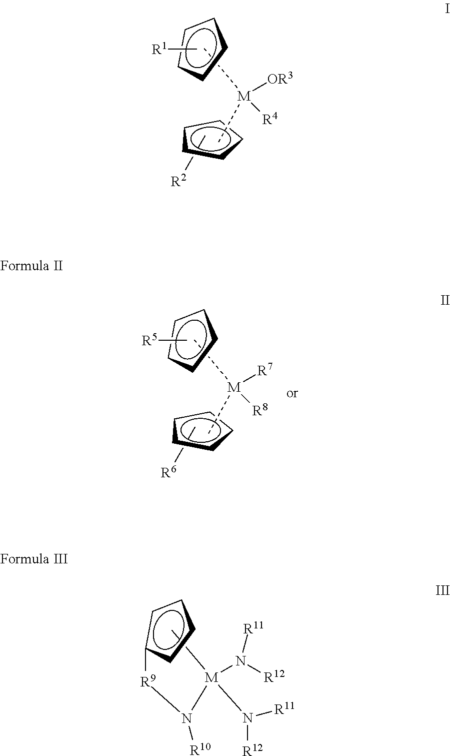

wherein (i) M is selected from Zr and Hf, (ii) R¹, R², R³, R⁴, R⁵, R⁶, R⁷ and R⁸ are each independently a C₁-C₆ linear alkyl, (iii) R⁹ is a C₁-C₄ group selected from —CH₂CH₂—, —CH₂CH₂CH₂—, —CH(Me)CH₂—, —CH₂CH(Me)-, —CH₂CH₂CH₂—, —CHMeCH₂CH₂—, and (iv) R¹⁰, R¹¹, and R¹² are each independently a C₁-C₆ linear alkyl.

In a further aspect of the first main aspect, the crystalline material is derived from one or more metallocene precursor having Formula I:

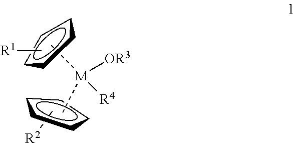

### Formula II:

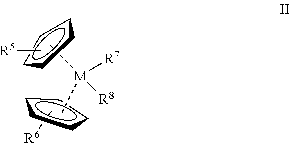

### or Formula III:

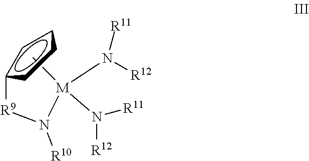

wherein (i) M is selected from Zr and Hf, (ii) R¹, R², R³, R⁴, R⁵, R⁶, R⁷ and R⁸ are each a methyl group, (iii) R⁹ is a C₁-C₄ group selected from —CH₂CH₂—, —CH₂CH₂CH₂—, —CH(Me)CH₂—, —CH₂CH(Me)-, —CH₂CH₂CH₂—, —CHMeCH₂CH₂—, and (iv) R¹⁰, R¹¹, and R¹² are each independently a C₁-C₆ linear alkyl.

In a further aspect of the first main aspect, there is hysteresis and remanent polarization in a polarization-electric field measurement. In a further aspect of the first main aspect, the film has a thickness of approximately 0.2 nm to approximately 10 nm.

In a second main aspect, a method of creating a ferroelectric device is provided. The method comprising: (i) providing a substrate; (ii) depositing a first electrode onto the substrate, the first electrode comprising tungsten, titanium nitride, molybdenum, ruthenium, or combinations thereof; (iii) depositing a ferroelectric layer onto the first electrode at a deposition temperature, the ferroelectric layer comprising zirconium and hafnium; (iv) depositing a second electrode onto the ferroelectric layer; and (v) annealing the first electrode at a temperature of 400 degrees Celsius or less.

In a further aspect of the second main aspect, an annealing step is conducted at a temperature greater than about 350 degrees Celsius. In a further aspect of the second main aspect, no process steps take place at a temperature greater than about 400 degrees Celsius. In a further aspect of the second main aspect, the ferroelectric layer comprises hafnium zirconium oxide. In a further aspect of the second main aspect, greater than 50% of the total volume of the first electrode is in a phase. In a further aspect of the second main aspect, the first electrode has a thickness of between about 4 nm and about 50 nm.

In a third main aspect, a method of creating a ferroelectric device is provided. The method comprising: (i) providing a substrate; (ii) depositing a first electrode onto the substrate at a first temperature; (iii) depositing a ferroelectric layer onto the first electrode at a second temperature; and (iv) depositing a second electrode onto the ferroelectric layer; (v) conducting an annealing step at a third temperature; wherein the first temperature, the second temperature, and the third temperature are less than or equal to 400 degrees Celsius.

In a further aspect of the third main aspect, the first temperature is between about 15 degrees Celsius and about 400 degrees Celsius. In a further aspect of the third main aspect, a thickness of the first electrode is between about 4 nm and about 50 nm. In a further aspect of the third main aspect, in the annealing step, the third temperature is greater than or equal to about 350 degrees Celsius and less than or equal to 400 degrees Celsius. In a further aspect of the third main aspect, no process steps take place at a temperature greater than about 400 degrees Celsius. In a further aspect of the third main aspect, the first electrode comprises tungsten, titanium nitride, molybdenum, ruthenium, or combinations thereof; and wherein the second electrode comprises titanium nitride, tungsten, molybdenum, or combinations thereof.

In a fourth main aspect, a ferroelectric device is provided. The ferroelectric device made by the process comprising: (i) providing a substrate; (ii) depositing a first electrode onto the substrate, the first electrode comprising tungsten; (iii) depositing a ferroelectric layer onto the first electrode at a deposition temperature, the ferroelectric layer comprising zirconium and hafnium; (iv) depositing a second electrode onto the ferroelectric layer; and (v) annealing the first electrode at a temperature of 400 degrees Celsius or less; wherein the first electrode comprises tungsten having a remnant polarization of greater than 50 μC/cm².

In a further aspect of the fourth main aspect, no process steps take place at a temperature greater than about 400 degrees Celsius. In a further aspect of the fourth main aspect, the ferroelectric layer comprises HfₓZr₁₋ₓO₂ or HfO₂ doped with La, Y, Gd, Ge, Si, or Sr.

In a further aspect of the fourth main aspect, the ferroelectric device has a critical dimension of 1000 nm or less, preferably about 300 μm or less.

A unit cell of ferroelectric random access memory device comprising the ferroelectric device of any of the preceding aspects.

A crossbar memory array comprising the ferroelectric device of any of the preceding aspects or the ferroelectric device created by the method of any of the preceding aspects comprising a memory unit cell.

A neuromorphic computing chip comprising the ferroelectric device of any of the preceding aspects, wherein the ferroelectric device is a synaptic device.

In another aspect, the advanced metallocene precursor is one or more of the precursors disclosed and/or claimed in U.S. Pat. No. 8,568,530 the contents of which is incorporated herein in its entirety.

This summary section does not specify every embodiment and/or incrementally novel aspect of the disclosed and claimed subject matter. Instead, this summary only provides a preliminary discussion of different embodiments and corresponding points of novelty over conventional techniques and the known art. For additional details and/or possible perspectives of the disclosed and claimed subject matter and embodiments, the reader is directed to the Detailed Description section and corresponding figures of the disclosure as further discussed below.

The order of discussion of the different steps described herein has been presented for clarity sake. In general, the steps disclosed herein can be performed in any suitable order. Additionally, although each of the different features, techniques, configurations, etc. disclosed herein may be discussed in different places of this disclosure, it is intended that each of the concepts can be executed independently of each other or in combination with each other as appropriate. Accordingly, the disclosed and claimed subject matter can be embodied and viewed in many different ways.

### BRIEF DESCRIPTION OF THE DRAWINGS

The accompanying drawings, which are included to provide a further understanding of the disclosed subject matter and are incorporated in and constitute a part of this specification, illustrate embodiments of the disclosed subject matter and together with the description serve to explain the principles of the disclosed subject matter. In the drawings:

FIG. 1 illustrates an embodiment of a ferroelectric device disclosed herein;

FIG. 2A is a graph showing transformation from alpha to beta phase.

FIG. 2B is a graph showing the peak shift after annealing.

FIG. 2C is a graph showing the remnant polarization after annealing.

FIG. 3A illustrates the effect of surface roughness and temperature;

FIG. 3B illustrates alpha phase as a function of temperature;

FIG. 3C illustrates remnant polarization after annealing at 400 degrees Celsius;

FIG. 4 illustrates wake-up effect for the BEOL compatible device;

FIG. 5 illustrates multi-level performance in FeCAP;

FIG. 6 illustrates the effect of the top electrode on the endurance of the ferroelectric device; and

FIG. 7 demonstrates the effect of the bottom electrode on the leakage response of the ferroelectric device.

### DEFINITIONS

Unless otherwise stated, the following terms used in the specification and claims shall have the following meanings for this application.

In this application, the use of the singular includes the plural, and the words “a,” “an” and “the” mean “at least one” unless specifically stated otherwise. Furthermore, the use of the term “including,” as well as other forms such as “includes” and “included,” is not limiting. Also, terms such as “element” or “component” encompass both elements or components including one unit and elements or components that include more than one unit, unless specifically stated otherwise. As used herein, the conjunction “and” is intended to be inclusive and the conjunction “or” is not intended to be exclusive, unless otherwise indicated. For example, the phrase “or, alternatively” is intended to be exclusive. As used herein, the term “and/or” refers to any combination of the foregoing elements including using a single element.

The term “about” or “approximately,” when used in connection with a measurable numerical variable, refers to the indicated value of the variable and to all values of the variable that are within the experimental error of the indicated value (e.g., within the 95% confidence limit for the mean) or within percentage of the indicated value (e.g., +10%, +5%), whichever is greater.

For purposes of this invention and the claims hereto, the numbering scheme for the Periodic Table Groups is according to the IUPAC Periodic Table of Elements.

The term “and/or” as used in a phrase such as “A and/or B” herein is intended to include “A and B,” “A or B,” “A” and “B.”

The terms “substituent,” “radical,” “group” and “moiety” may be used interchangeably.

As used herein, the terms “metal-containing complex” (or more simply, “complex”) and “precursor” are used interchangeably and refer to a metal-containing molecule or compound which can be used to prepare a metal-containing film by a deposition process such as, for example, ALD or CVD. The metal-containing complex may be deposited on, adsorbed to, decomposed on, delivered to, and/or passed over a substrate or surface thereof, as to form a metal-containing film.

As used herein, the term “metal-containing film” includes not only an elemental metal film as more fully defined below, but also a film which includes a metal along with one or more elements, for example a metal nitride film, metal silicide film, a metal carbide film and the like.

As used herein, the terms “elemental metal,” “elemental metal film” and “pure metal film” are used interchangeably and refer to a film which consists of, or consists essentially of, pure metal. For example, an elemental metal film may include 100% pure metal or the elemental metal film may include at least about 70%, at least about 80%, at least about 90%, at least about 95%, at least about 96%, at least about 97%, at least about 98%, at least about 99%, at least about 99.9%, or at least about 99.99% pure metal along with one or more impurities. However, a film comprising an elemental metal is distinguished from binary films including a metal and a non-metal (e.g., C, N, O) and ternary films including a metal and two non-metals (e.g., C, N, O), though, a film comprising elemental metal may include some amount of impurities. Unless context dictates otherwise, the term “metal film” shall be interpreted to mean an elemental metal film.

As used herein, the terms “deposition process” and “thermally depositing” are used to refer to any type of deposition technique, including but not limited to, CVD and ALD. In various embodiments, CVD may take the form of conventional (i.e., continuous flow) CVD, liquid injection CVD, plasma-enhanced CVD, or photo-assisted CVD. CVD may also take the form of a pulsed technique, i.e., pulsed CVD. ALD is used to form a metal-containing film by vaporizing and/or passing at least one metal complex disclosed herein over a substrate surface. For conventional ALD processes see, for example, George S. M., et al., J. Phys. Chem., 1996, 100, 13121-13131. In other embodiments, ALD may take the form of conventional (i.e., pulsed injection) ALD, liquid injection ALD, photo-assisted ALD, plasma-assisted ALD, or plasma-enhanced ALD. The term “vapor deposition process” further includes various vapor deposition techniques described in Chemical Vapour Deposition: Precursors, Processes, and Applications; Jones, A. C.; Hitchman, M. L., Eds. The Royal Society of Chemistry: Cambridge, 2009; Chapter 1, pp 1-36.

Unless otherwise indicated, “alkyl” refers to hydrocarbon groups which can be linear, branched (e.g., methyl, ethyl, propyl, isopropyl, tert-butyl and the like), cyclic (e.g., cyclohexyl, cyclopropyl, cyclopentyl and the like) or multicyclic (e.g., norbornyl, adamantly and the like). Suitable acyclic groups can be methyl, ethyl, n- or iso-propyl, n-, iso, or tert-butyl, linear or branched pentyl, hexyl, heptyl, octyl, decyl, dodecyl, tetradecyl and hexadecyl. Unless otherwise stated, alkyl refers to 1-10 carbon atom moieties. The cyclic alkyl groups may be mono cyclic or polycyclic. Suitable examples of mono-cyclic alkyl groups include substituted cyclopentyl, cyclohexyl, and cycloheptyl groups. The substituents may be any of the acyclic alkyl groups described herein. As mentioned herein the cyclic alkyl groups may have any of the acyclic alkyl groups as substituent. These alkyl moieties may be substituted or unsubstituted.

“Halogenated alkyl” refers to a linear, cyclic, or branched saturated alkyl group as defined above in which one or more of the hydrogens has been replaced by a halogen (e.g., F, Cl, Br, and I). Thus, for example, a fluorinated alkyl (a.k.a. “fluoroalkyl”) refers to a linear, cyclic or branched saturated alkyl group as defined above in which one or more of the hydrogens has been replaced by fluorine (e.g., trifluoromethyl, pefluoroethyl, 2,2,2-trifluoroethyl, prefluoroisopropyl, perfluorocyclohexyl and the like). Such haloalkyl moieties (e.g., fluoroalkyl moieties), if not perhalogenated/multihalogentated, may be unsubstituted or further substituted.

The section headings used herein are for organizational purposes and are not to be construed as limiting the subject matter described. All documents, or portions of documents, cited in this application, including, but not limited to, patents, patent applications, articles, books, and treatises, are hereby expressly incorporated herein by reference in their entirety for any purpose. In the event that any of the incorporated literature and similar materials defines a term in a manner that contradicts the definition of that term in this application, this application controls.

### DETAILED DESCRIPTION

It is to be understood that both the foregoing general description and the following detailed description are illustrative and explanatory, and are not restrictive of the subject matter, as claimed. The objects, features, advantages and ideas of the disclosed subject matter will be apparent to those skilled in the art from the description provided in the specification, and the disclosed subject matter will be readily practicable by those skilled in the art on the basis of the description appearing herein. The description of any “preferred embodiments” and/or the examples which show preferred modes for practicing the disclosed subject matter are included for the purpose of explanation and are not intended to limit the scope of the claims.

It will also be apparent to those skilled in the art that various modifications may be made in how the disclosed subject matter is practiced based on described aspects in the specification without departing from the spirit and scope of the disclosed subject matter disclosed herein.

I. Ferroelectric Device with Multilevel Switching

The ferroelectric devices of the instant disclosure can take many forms. In a preferred embodiment, the ferroelectric device is incorporated into Ferroelectric Random Access Memory (FeRAM, F-RAM, or FRAM). Moreover, the ferroelectric device can be used also as capacitor to program different remanent charge polarization states by applying different field. This specific implementation is generally used in Ferroelectric RAM (FeRAM) application. In an alternative embodiment, the ferroelectric device is a Ferroelectric Tunnel Junction (FTJ). FTJs have recently been studied as one of the best candidates as memristor or artificial synapse thanks to its unique analog-type programming fundamental for neuromorphic computing applications. Use of ALD HZO film deposited at high T with specific Hf and Zr precursors sandwiched between a TiN electrode and a W electrode, and specific Post Metal Anneal (PMA) allows for multilevel programming up to 4 levels with retention better than current state of the art for FTJ that generally uses bilayer stack with higher complexity. This disclosure paves the way for future implementation of FTJ in neuromorphic computing chips.

The instant disclosure demonstrates a new technique to introduce asymmetry between a top electrode and a bottom electrode. This is facilitated by the high temperature (>300 C) atomic layer deposition (ALD) of Hafnium Zirconium Oxide (HZO) using the alternate cycling of the Hf and Zr precursors with ozone pulsing for oxidation in between.

In the state-of-the-art system of fabricating ferroelectric memory devices, typically FE materials are deposited using lower temperature ALD that makes the film amorphous as-deposited and hence non-FE, followed by a high temperature annealing (>500 C) to crystallize the film and activate the FE properties of the film. For an FTJ with an interfacial layer an additional processing step may be needed to deposit the interfacial material. The instant process integration and stack allow for as-deposited FE film because of the precursor's ability to handle high temperature (>300 C). Additionally, the process inherently oxidizes the bottom electrode (due to its high temperature and highly reactive ozone process) to create interfacial metal oxide that introduces the asymmetry required for FTJ operation. Further annealing at higher than the deposition temperature can be introduced to improve the FE memory window and reliability metric like retention and endurance.

Additionally, the optimization of HZO film, the ferroelectric stack demonstrate good tunability. Proper choice of ALD deposition temperature, ozone dilution and post-metal anneal conditions are fundamental to obtain the desired orthorhombic phase needed for ferroelectric multi-domain switching that is essential for multi-level switching in ferroelectric devices.

The instant disclosure for the first time shows BEOL compatible process with a Hafnium Zirconium Oxide (HZO) switching layer sandwiched between symmetric W and W electrodes with multilevel programming up to 4 states and good retention of these states for at least 104 s. During HZO deposition an oxidized interfacial layer (WOₓ) is created by oxidizing the W bottom electrode interface. An advantage of this step is that is occurs concomitantly in the deposition process and an additional process step is not needed.

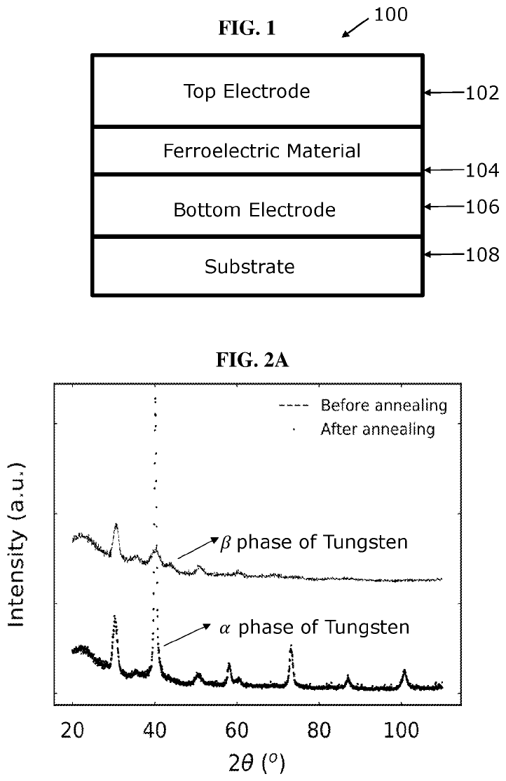

The ferroelectric device 100 of FIG. 1 comprises a top electrode 102, a layer of ferroelectric material 104, a bottom electrode 106, and a substrate 108. In a preferred embodiment, the top electrode and the bottom electrode comprise tungsten, and the ferroelectric material comprises a thin film of hafnium and zirconium oxide (HZO).

The inherently ferroelectric thin film materials and the methods of their use, which address the forgoing issues, are disclosed here and in U.S. Provisional Patent Application No. 63/040,097 filed on Jun. 17, 2020 (Attorney Docket No. P20-094 US-PRO), and PCT Application No. PCT/EP2021/066028 filed Jun. 15, 2021 (P20-094 WO-PCT). These applications are incorporated by reference in their entireties. In doing so, the materials and methods described herein reduce processing time making them especially amenable to the demands of current manufacturing procedures. The disclosure involves the FTJs having 9 or more distinct resistance levels. Those skilled in the art can readily appreciate the potential for subsequent optimization of interfaces, electrodes, and thermal processing conditions after deposition of these materials.

### II. Inherently Ferroelectric Materials

As set forth above, the disclosed and claimed subject matter relates to crystalline ferroelectric thin film materials that include a mixture of hafnium oxide and zirconium oxide having a substantial (i.e., approximately 40% or more) portion of the material in a ferroelectric phase and methods for preparing and depositing these materials. In a further aspect, the ferroelectric materials have a majority volume fraction of a ferroelectric phase. Significantly, these materials exhibit ferroelectric properties without the need for further processing, such as a subsequent capping step or annealing step. To be ferroelectric, the produced materials have one or more of (i) remanent polarization or (ii) a polarization field curve with hysteresis and a loop opening.

In order to be ferroelectric, the material must have an arrangement of atoms that can support ferroelectricity in some fraction of the film. It is preferable that a substantial portion of the volume of the film have an arrangement of atoms that can support ferroelectricity. It is understood that for thin films, doped materials, and some laminated materials, the phase distribution in the material may not be easily determined by x-ray diffraction. In this case, any other suitable technique for establishing the phase of the film, such as Raman spectroscopy, infrared spectroscopy, x-ray absorption spectroscopy, transmission electron microscopy, or combinations thereof, may be used to determine the phase distribution. For example, https://onlinelibrary.wiley.com/doi/full/10.1002/pssb.201900285 describes a technique for ascertaining the phase of a film to within approximately 10%.

The material can be comprised of any suitable molar ratio of hafnium oxide and zirconium oxide-ratios between 1:3 and 3:1 are preferred. The thickness of the ferroelectric material is any thickness that is suitable for the given application; the material can be made thicker to increase the remanent polarization or reduce the electrical leakage current through the thickness of the material or be made thinner because of geometric constraints or to increase the capacitance of the film.

The preferred range of thicknesses for this ferroelectric film is approximately 0.2 nm to approximately 20 nm and is more preferably approximately 0.2 nm to 10 nm. It is also preferable that the materials form films having a thickness of approximately 10 nm and less. In some embodiments it is preferable that the materials form films having a thickness of approximately 5 nm and less.

As discussed above, however, preferred and/or desired thicknesses will change depending on specific application. Thus, as noted previously, in some embodiments the materials exhibit ferroelectric properties as thin films of approximately 20 nm or less. In a further aspect the materials exhibit ferroelectric properties as thin films of approximately 15 nm or less. In a further aspect, the materials exhibit ferroelectric properties as thin films of approximately 10 nm or less. In a further aspect, the materials exhibit ferroelectric properties as thin films of approximately 5 nm or less. In a further aspect, the materials exhibit ferroelectric properties as thin films of approximately 3 nm or less. In a further aspect, the materials exhibit ferroelectric properties as thin films of approximately 1 nm or less. In a further aspect, the materials exhibit ferroelectric properties as thin films of approximately 0.5 nm or less. In a further aspect, the materials exhibit ferroelectric properties as thin films of approximately 0.2 nm or less. In a further aspect, the materials exhibit ferroelectric properties as thin films of between approximately 0.2 nm to approximately 20 nm. In a further aspect, the materials exhibit ferroelectric properties as thin films of between approximately 0.2 nm to approximately 15 nm. In a further aspect, the materials exhibit ferroelectric properties as thin films of between approximately 0.2 nm to approximately 10 nm. In a further aspect, the materials exhibit ferroelectric properties as thin films of between approximately 0.2 nm to approximately 5 nm. In a further aspect, the materials exhibit ferroelectric properties as thin films of between approximately 0.2 nm to approximately 3 nm. In a further aspect, the materials exhibit ferroelectric properties as thin films of between approximately 0.2 nm to approximately 1 nm. In a further aspect, the materials exhibit ferroelectric properties as thin films of between approximately 0.2 nm to approximately 1 nm.

### Bottom Electrode

The preferred range of thicknesses for the bottom electrode is approximately 1 nm to approximately 25 nm and is more preferably approximately 4 nm to 15 nm. It is also preferable that the materials form films having a thickness of approximately 10 nm and less. In some embodiments it is preferable that the materials form films having a thickness of approximately 5 nm and less.

In the disclosed and claimed materials, a substantial portion constituting approximately 40% or more of the crystalline material is in a ferroelectric phase, thus the total non-ferroelectric atomic arrangement components are less than approximately 60% of the total volume of the material. In another embodiment, the total non-ferroelectric atomic arrangement components are less than approximately 50% of the total volume of the material. In another embodiment, the total non-ferroelectric atomic arrangement components are less than approximately 40% of the total volume of the material. In another embodiment, the total non-ferroelectric atomic arrangement components are less than approximately 30% of the total volume of the material. In another embodiment, the total non-ferroelectric atomic arrangement components are less than approximately 25% of the total volume of the material. In another embodiment, the total non-ferroelectric atomic arrangement components are less than approximately 20% of the total volume of the material. In another embodiment, the total non-ferroelectric atomic arrangement components are less than approximately 15% of the total volume of the material. In another embodiment, the total non-ferroelectric atomic arrangement components are less than approximately 10% of the total volume of the material. In another embodiment, the total non-ferroelectric atomic arrangement components are less than approximately 5% of the total volume of the material.

Moreover, in the disclosed and claimed materials less than approximately 60% of the of the total volume of the material constitutes a non-ferroelectric monoclinic phase component. Thus, in one embodiment of the disclosed and claimed materials, a monoclinic phase component is less than approximately 50% of the total volume of the material. In another embodiment, a monoclinic phase component is less than approximately 40% of the total volume of the material. In another embodiment, a monoclinic phase component is less than approximately 30% of the total volume of the material. In another embodiment, a monoclinic phase component is less than approximately 25% of the total volume of the material. In another embodiment, a monoclinic phase component is less than approximately 20% of the total volume of the material. In another embodiment, a monoclinic phase component is less than approximately 15% of the total volume of the material. In another embodiment, a monoclinic phase component is less than approximately 10% of the total volume of the material. In another embodiment, a monoclinic phase component is less than approximately 5% of the total volume of the material.

The inherently ferroelectric materials are derived from metallocene precursor from advanced metallocene precursors having the Formula I (“(R¹—Cp)(R²—Cp)-M-(OR³)(R⁴)” where Cp is a cyclopentadienyl group) and/or Formula II (“(R⁵—Cp)(R⁶-Cp)-M-(R⁷)(R⁸)” where Cp is a cyclopentadienyl group):

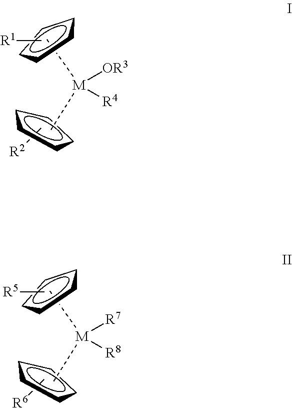

where: M=Zr or Hf; and
R¹, R², R³, R⁴, R⁵, R⁶, R⁷ and R⁸ are each independently selected from a C₁-C₆ linear alkyl, a C₁-C₆ branched alkyl, a C₁-C₆ halogenated linear alkyl and a C₁-C₆ halogenated branched alkyl.

In another aspect, in Formula I each of R¹, R², R³, R⁴, R⁵, R⁶, R⁷ and R⁸ is preferably a C₁-C₆ linear alkyl. In a further aspect, in Formula I each of R¹, R², R³, R⁴, R⁵, R⁶, R⁷ and R⁸ is preferably the same C₁-C₆ linear alkyl. In a further aspect, in Formula I each of R¹, R², R³, R⁴, R⁵, R⁶, R⁷ and R⁸ is preferably a methyl group. In a further aspect, in Formula I each of R¹, R², R³, R⁴, R⁵, R⁶, R⁷ and R⁸ is preferably an ethyl group. In a further aspect, in Formula I each of R¹, R², R⁵ and R⁶ is preferably an ethyl group. In a further aspect, in Formula I each of R³, R⁴, R⁷ and R⁸ is preferably a methyl group. In a further aspect, in Formula I each of R¹, R², R⁵ and R⁶ is preferably an ethyl group and each of R³, R⁴, R⁷ and R⁸ is preferably a methyl group.

In another aspect, in Formula II each of R¹, R², R³, R⁴, R⁵, R⁶, R⁷ and R⁸ is preferably a C₁-C₆ linear alkyl. In a further aspect, in Formula II each of R¹, R², R³, R⁴, R⁵, R⁶, R⁷ and R⁸ is preferably the same C₁-C₆ linear alkyl. In a further aspect, in Formula II each of R¹, R², R³, R⁴, R⁵, R⁶, R⁷ and R⁸ is preferably a methyl group. In a further aspect, in Formula II each of R¹, R², R³, R⁴, R⁵, R⁶, R⁷ and R⁸ is preferably an ethyl group. In a further aspect, in Formula II each of R¹, R², R⁵ and R⁶ is preferably an ethyl group. In a further aspect, in Formula II each of R³, R⁴, R⁷ and R⁸ is preferably a methyl group. In a further aspect, in Formula II each of R¹, R², R⁵ and R⁶ is preferably an ethyl group and each of R³, R⁴, R⁷ and R⁸ is preferably a methyl group.

In another aspect, the advanced metallocene precursor is one or more of (MeCp)₂Zr(OMe)Me, (MeCp)₂Hf(OMe)Me, (MeCp)₂Zr(Me)₂, (MeCp)₂Hf(Me)₂, (EtCp)₂Zr(OMe)Me, (EtCp)₂Hf(OMe)Me, (EtCp)₂Zr(Me)₂, (EtCp)₂Hf(Me)₂, and combinations thereof.

In another aspect, the advanced metallocene precursor is one or more mixture of (MeCp)₂Zr(OMe)Me and (MeCp)₂Hf(OMe)Me, a mixture of (MeCp)₂Hf(Me)₂ and (MeCp)₂Hf(Me)₂. (EtCp)₂Zr(OMe)Me and (EtCp)₂Hf(OMe)Me and a mixture of (EtCp)₂Hf(Me)₂ and (EtCp)₂Hf(Me)₂.

In another aspect, the advanced metallocene precursor is one or more of the precursors having the Formula III.

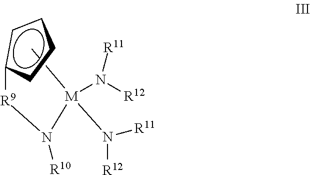

wherein (i) M is selected from Zr and Hf, (iii) R⁹ is a C₁-C₄ group selected from —CH₂CH₂—, —CH₂CH₂CH₂—, —CH(Me)CH₂—, —CH₂CH(Me)-, —CH₂CH₂CH₂—, —CHMeCH₂CH₂—, and (iv) R¹⁰, R¹¹, and R¹² are each independently a C₁-C₆ linear alkyl. R⁹ is preferably a —CH₂CH₂— group.

### III. Methods for Preparing and Depositing Inherently Ferroelectric Materials

As noted above, in another aspect the disclosed and claimed subject matter is directed to a process for preparing and/or depositing the inherently ferroelectric materials disclosed herein. In this process, the disclosed and claimed inherently ferroelectric materials are prepared by iterative depositions and purges (i) of a metallocene precursor and (ii) a reactant.

### A. Metallocene Precursors

As noted above, the ferroelectric materials are derived from advanced metallocene precursors having the Formula I (“(R¹—Cp)(R²—Cp)-M-(OR₃)(R⁴)” where Cp is a cyclopentadienyl group) and/or Formula II (“(R⁵—Cp)(R⁶—Cp)-M-(R⁷)(R⁸)” where Cp is a cyclopentadienyl group):

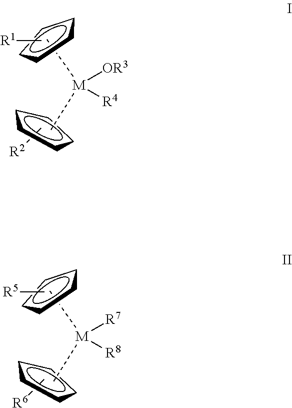

where: M=Zr or Hf; and
R¹, R², R³, R⁴, R⁵, R⁶, R⁷ and R⁸ are each independently selected from a C₁-C₆ linear alkyl, a C₁-C₆ branched alkyl, a C₁-C₆ halogenated linear alkyl and a C₁-C₆ halogenated branched alkyl.

In another aspect, in Formula I each of R¹, R², R³, R⁴, R⁵, R⁶, R⁷ and R⁸ is preferably a C₁-C₆ linear alkyl. In a further aspect, in Formula I each of R¹, R², R³, R⁴, R⁵, R⁶, R⁷ and R⁸ is preferably the same C₁-C₆ linear alkyl. In a further aspect, in Formula I each of R¹, R², R³, R⁴, R⁵, R⁶, R⁷ and R⁸ is preferably a methyl group. In a further aspect, in Formula I each of R¹, R², R³, R⁴, R⁵, R⁶, R⁷ and R⁸ is preferably an ethyl group. In a further aspect, in Formula I each of R¹, R², R⁵ and R⁶ is preferably an ethyl group. In a further aspect, in Formula I each of R³, R⁴, R⁷ and R⁸ is preferably a methyl group. In a further aspect, in Formula I each of R¹, R², R⁵ and R⁶ is preferably an ethyl group and each of R³, R⁴, R⁷ and R⁸ is preferably a methyl group.

In another aspect, in Formula II each of R¹, R², R³, R⁴, R⁵, R⁶, R⁷ and R⁸ is preferably a C₁-C₆ linear alkyl. In a further aspect, in Formula II each of R¹, R², R³, R⁴, R⁵, R⁶, R⁷ and R⁸ is preferably the same C₁-C₆ linear alkyl. In a further aspect, in Formula II each of R¹, R², R³, R⁴, R⁵, R⁶, R⁷ and R⁸ is preferably a methyl group. In a further aspect, in Formula II each of R¹, R², R³, R⁴, R⁵, R⁶, R⁷ and R⁸ is preferably an ethyl group. In a further aspect, in Formula II each of R¹, R², R⁵ and R⁶ is preferably an ethyl group. In a further aspect, in Formula II each of R³, R⁴, R⁷ and R⁸ is preferably a methyl group. In a further aspect, in Formula II each of R¹, R², R⁵ and R⁶ is preferably an ethyl group and each of R³, R⁴, R⁷ and R⁸ is preferably a methyl group.

In another aspect, the advanced metallocene precursor is one or more of (MeCp)₂Zr(OMe)Me, (MeCp)₂Hf(OMe)Me, (MeCp)₂Zr(Me)₂, (MeCp)₂Hf(Me)₂, (EtCp)₂Zr(OMe)Me, (EtCp)₂Hf(OMe)Me, (EtCp)₂Zr(Me)₂, (EtCp)₂Hf(Me)₂, and combinations thereof.

In another aspect, the advanced metallocene precursor is one or more mixture of (MeCp)₂Zr(OMe)Me and (MeCp)₂Hf(OMe)Me, a mixture of (MeCp)₂Hf(Me)₂ and (MeCp)₂Hf(Me)₂, (EtCp)₂Zr(OMe)Me and (EtCp)₂Hf(OMe)Me and a mixture of (EtCp)₂Hf(Me)₂ and (EtCp)₂Hf(Me)₂.

In another aspect, the advanced metallocene precursor is one or more of the precursors having the Formula III.

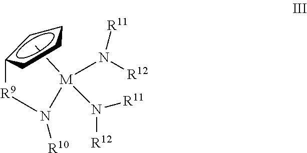

wherein (i) M is selected from Zr and Hf, (iii) R⁹ is a C₁-C₄ group selected from —CH₂CH₂—, —CH₂CH₂CH₂—, —CH(Me)CH₂—, —CH₂CH(Me)-, —CH₂CH₂CH₂—, —CHMeCH₂CH₂—, and (iv) R¹⁰, R¹¹, and R¹² are each independently a C₁-C₆ linear alkyl.

In another aspect, the advanced metallocene precursor having the Formula III is one or more mixture of (MeNCH₂CH₂Cp)Hf(NMe₂)₂, (MeNCH₂CH₂Cp)Hf(NEtMe)₂, (MeNCH₂CH₂CH₂Cp)Hf(NMe₂)₂, (MeNCH₂CH₂CH₂Cp)Hf(NEtMe)₂, (MeNC(Me)HCH₂Cp)Hf(NMe₂)₂, (MeNC(Me)HCH₂Cp)Hf(NEtMe)₂, (MeNCH₂CH(Me)Cp)Hf(NEtMe)₂, (MeNCH₂CH₂Cp)Zr(NEtMe)₂, (MeNCH₂CH₂CH₂Cp)Zr(NEtMe)₂, (MeNC(Me)HCH₂Cp)Zr(NEtMe)₂, (MeNCH₂CH(Me)Cp)Zr(NEMe)₂ (MeNCH₂CH(Me)Cp)Hf(NMe₂)₂, (MeNCH₂CH₂Cp)Zr(NMe₂)₂, (MeNCH₂CH₂CH₂Cp)Zr(NMe₂)₂, (MeNC(Me)HCH₂Cp)Zr(NMe₂)₂, (MeNCH₂CH(Me)Cp)Zr(NMe₂)₂

In general, suitable precursors for preparing the inherently ferroelectric materials are able to be deposited at or near the crystallization temperature of the desired ferroelectric material, typically between approximately 200° C. and approximately 570° C. depending on the composition of the material, substrate, and reactor design, among other factors. A preferred temperature is approximately 300° C. (or generally between approximately 280° C. and approximately 300° C.), and the preferred temperature range is below approximately 450° C. and more preferably below approximately 340° C. However, those skilled in the art should recognize that other temperatures may be possible depending on the specific precursor used and that such precursors also fall within the scope of the disclosed and claimed subject matter. It should further be noted that with certain precursors besides the ones listed here, decomposition of the precursor can occur within the temperature range described. Decomposition products, in particular carbon and organic species, can become incorporated in the deposited hafnium oxide or zirconium oxide material. While this incorporation of carbon may assist with the stabilization of the ferroelectric phase, it may be undesirable for material purity reasons. Thus, as discussed above, the preferred carbon content of the material is below approximately 6 atomic percent.

### B. Reactant

The reactant is a reaction gas containing one or more of oxygen (e.g., ozone, elemental oxygen, molecular oxygen/O₂), water, hydrogen peroxide and nitrous oxide. In one embodiment, ozone is a preferred reactant gas. In another embodiment, water is a preferred reactant gas.

### C. Process Steps

The process for preparing and depositing the inherently ferroelectric materials descried herein comprises a substrate that undergoes a sputtering PVD cycle to deposit the tungsten bottom electrode. Other methods for deposition of the bottom electrode include, but are not limited to, CVD, ALD, or e-beam deposition. Following the deposition of the bottom electrode is an ALD cycle in which the bottom electrode is exposed to vapor to form and deposit an inherently ferroelectric material as thin film layer. Layer 200 was formed and exhibits ferroelectric properties as such (i.e., as deposited). Those skilled in the art recognize, of course, that layer could be subsequently annealed and/or capped as desired but that doing so was not necessary to observe ferroelectric behavior of the layer as deposited. For example, energy can subsequently be applied to the material by, but not limited to, thermal, plasma, pulsed plasma, helicon plasma, high density plasma, inductively coupled plasma, X-ray, e-beam, photon, remote plasma methods, and combinations thereof.

The constituents of vapor change during ALD cycle. In particular, bottom electrode is alternatingly exposed to metallocene precursor followed by a purge and then exposed to reactant followed by another purge. This process continues until a desired thickness for ferroelectric layer is obtained. Although ALD is a preferred vapor deposition technique, any suitable vapor phase deposition technique can be utilized, such as CVD or pulsed CVD. Thus, for example, ALD cycle could be replaced by a CVD process in which metallocene precursor and reactant are provided as a mixture in vapor and provided simultaneously to substrate.

An appropriate molar ratio of hafnium oxide to zirconium oxide can be created by several methods, including introducing a hafnium-containing precursor during a fraction of these cycles, and a zirconium-containing precursor during other cycles. The cycles could alternate, be grouped together, or arranged in any other suitable sequence to produce the overall desired molar ratio, as both intimately blended materials and nanolaminated materials have been shown to have desirable ferroelectric properties. It should be noted that other elements may be added into the hafnium oxide-zirconium oxide material by adding appropriate precursors either along with the hafnium and zirconium precursors, or in separate cycles.

The bottom electrode on which the inherently ferroelectric material is formed as layer can include any suitable material, including semiconducting materials like silicon, germanium, III-V materials, transition metal dichalcogenides, and mixtures thereof, metals and conductive ceramics like titanium nitride, titanium, tantalum, tantalum nitride, tungsten, platinum, rhodium, molybdenum, cobalt, ruthenium, palladium, or mixtures thereof, or dielectrics like silicon oxide, silicon nitride, aluminum oxide, titanium oxide, other ferroelectric materials, including compositions of hafnium oxide and zirconium oxide, magnetic materials, and mixtures or stacks thereof. In the illustrated embodiment, the bottom electrode comprises tungsten.

Optionally, bottom electrode can be patterned or textured, as appropriate, with any suitable topography, including flat surfaces, trenches, vias, or nanostructured surfaces. This list represents typical substrates that may be useful in ferroelectric applications, but should not be considered limiting, as many other suitable compositions and surface patterns would be obvious to those skilled in the art. In this regard, it is known that the substrate can have some influence on the atomic arrangement and phase of the film formed thereon, including affecting the crystalline orientation and crystallization temperature of the film. Regardless of the particular substrate and the extent of this effect, the inherently ferroelectric materials described herein and deposited on such substrates nevertheless have a substantial fraction of their volume in the ferroelectric phase as deposited. In the illustrated embodiment, the bottom electrode has a low roughness.

Another embodiment of a process for preparing and depositing the inherently ferroelectric materials is descried herein. In this embodiment, a mixed hafnium oxide and zirconium oxide inherently ferroelectric material is prepared and deposited as layer with a thickness of approximately 7.5 nm on a stacked substrate of PVD W (which is in direct contact with the ferroelectric material), a thermally grown SiO₂ layer and a Si wafer. Layer was formed without further thermal processing or capping. In this embodiment, the molar ratio of hafnium oxide to zirconium oxide is approximately 1:1, with a margin of error of approximately 10%. The ferroelectric material is prepared and deposited as layer 301 from the vapor by ALD by alternating First Cycle 303 (which includes the steps of (i) pulsing (MeCp)₂Zr(OMe)Me 304, (ii) purging, (iii) pulsing ozone 305 and (iv) purging) and Second Cycle 306 (which includes the steps of (i) pulsing (MeCp)₂Hf(OMe)Me 307, (ii) purging, (iii) pulsing ozone 308 and (iv) purging).

Those skilled in the art will recognize that other precursors, such as (MeCp)₂HfMe₂ and (MeCp)₂ZrMe₂ and other reactants, such as water, hydrogen peroxide or oxygen plasma, may also or alternatively be used. Those skilled in the art will further recognize that the pulsing and purging times can each respectively vary depending on equipment. In one embodiment, pulses last from approximately 2 to approximately 3 seconds followed by a purge of approximately 10 seconds. In another embodiment, pulses last from approximately 10 to approximately 15 seconds followed by a purge of approximately 30 seconds to approximately 60 seconds. In another embodiment, the order in which the precursors are deposited can be reversed.

An embodiment of a process for preparing and depositing the bottom electrode descried herein using CVD. The method includes several steps that can be augmented with additional and/or optional steps. Step 1 includes providing a substrate at a deposition temperature of between approximately 200° C. and approximately 500° C., but that is preferably at or around approximately 350° C. (e.g., above approximately 225° C. and at or below approximately 300° C.) and below 340° C.

An embodiment of a process for preparing and depositing the inherently ferroelectric materials descried herein using ALD. The method includes several steps that can be augmented with additional and/or optional steps. Step 1 includes providing a substrate at a deposition temperature of between approximately 265° C. and approximately 500° C., but that is preferably at or around approximately 300° C. (e.g., above approximately 285° C. and at or below approximately 300° C.) and below 340° C. Step 2 includes (i) exposing the substrate to a first precursor containing hafnium or zirconium or both hafnium and zirconium that does not decompose at the deposition temperature and (ii) purging. Step 3 includes (i) exposing the substrate to a reaction gas containing oxygen and (ii) purging. Step 4 includes (i) exposing the substrate to a second precursor containing zirconium or hafnium or both hafnium and zirconium that does not decompose at the deposition temperature and (ii) purging. Step 5 includes exposing the substrate to a reaction gas containing oxygen. Optional Step 6 includes repeating Steps 2-5 until a film of hafnium oxide and zirconium oxide of desired thickness is formed with a molar ratio between approximately 1:3 and approximately 3:1.

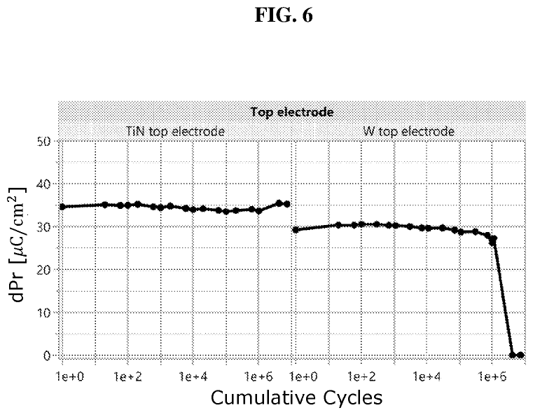

In a process of the instant disclosure, the inherently ferroelectric materials are formed and deposited as films having a substantial volume fraction of a ferroelectric phase as deposited (i.e., without further annealing and/or capping) and as measured by a phase determining technique or electrical testing known to those skilled in the art (e.g., XRD, XAS, TEM, polarization-voltage testing, piezo force microscopy, or combinations thereof). The metallocene precursors utilized and/or that can be utilized in the process of FIG. 6 include all of those disclosed and discussed above and include, in particular, (MeCp)₂Zr(OMe)Me, (MeCp)₂Hf(OMe)Me, (MeCp)₂Zr(Me)₂ and (MeCp)₂Hf(Me)₂. The reaction gas containing oxygen of Step 3 and/or Step 5 is preferably ozone. Those skilled in the art will recognize that other reaction gases can be used including those specifically described above (e.g., water, hydrogen peroxide).

In certain embodiments, the ferroelectric device 100 can be incorporated into a unit cell of ferroelectric random access memory (FeRAM). In further embodiments, the ferroelectric device can be incorporated into a crossbar array or a memory unit cell of a memory device. In certain embodiments, the ferroelectric device 100 can be incorporated into a neuromorphic computing chip or a synaptic device such as a synaptic memristor or a synaptic transistor.

FIG. 1 illustrates an embodiment of the HZO ferroelectric stack 100 of the instant disclosure. FIG. 1 shows a top electrode 102, a layer of ferroelectric material 104, a bottom electrode 106, and a substrate 108. In a preferred embodiment the stack comprises of W (5 nm)/HZO (5 nm)/W (5 nm) after 400° C. anneal for 2 min in N₂.

The bottom (first) electrode and the top (second) electrode may be metallic or semiconducting electrodes having a thickness to ensure good conduction. In the illustrated embodiment, the top electrode comprises tungsten. In other embodiments, the top electrode may comprise any of titanium nitride, tungsten, molybdenum, nickel, ruthenium, platinum, and aluminum. In an illustrated embodiment, 5 nm or 10 nm thick W is used. Circular testing electrodes comprise 50 nm TiN.

### EXAMPLES

Reference will now be made to more specific embodiments of the present disclosure and experimental results that provide support for such embodiments. The examples are given below to more fully illustrate the disclosed subject matter and should not be construed as limiting the disclosed subject matter in any way.

### Device Fabrication

Bottom electrodes were grown in a sputtering system on a coupon with a carrier wafer. The temperatures stated are the setpoint temperature of the chamber. HZO films were grown by ALD using bis(methylcyclopentadienyl) methoxymethyl-hafnium and bis(methylcyclopentadienyl) methoxymethyl-zirconium precursors at 330 degrees C., 4% ozone. HZO deposition was then followed by 50 Å deposition of W top electrode. Circular electrodes for electrical testing are TiN 500 Å being defined by a shadow mask, or by contact lithography, and grown by an Endura sputtering chamber at 250 degrees C. The post-metal annealing at 400 degrees Celsius for 5 minutes was performed after the W top electrode deposition.

### HZO Film Growth

The FE HZO film is grown by atomic layer deposition at 330° C. with an exposure sequence of (Bis(methylcyclopentadienyl) methoxymethyl-hafnium)/ozone/(Bis(methylcyclopentadienyl) methoxymethyl-zirconium)/ozone comprising one HZO supercycle. The Hf precursor could also be (MeNCH₂CH₂Cp)Hf(NMe₂)₂ and the Zr precursor could also be (MeNCH₂CH₂Cp)Zr(NMe₂)₂. Bis(methylcyclopentadienyl)methoxymethyl-hafnium, bis(methylcyclopentadienyl)methoxymethyl-zirconium, (MeNCH₂CH₂Cp)Hf(NMe₂)₂, and (MeNCH₂CH₂Cp)Zr(NMe₂) 2 are all proprietary chemicals from EMD Electronics. These cyclopentadienyl precursors have ALD window at higher (300° C.-400° C.) temperatures compared with amide-type precursors, allowing for lower temperature PMA process in order to get desired HZO crystalline grains. We have deposited the films at 4% ozone concentration. Bis(methylcyclopentadienyl) methoxymethyl-hafnium and bis(methylcyclopentadienyl) methoxymethyl-zirconium precursors were kept at an ampule temperature of 125° C. and 70° C. respectively during deposition. (MeNCH₂CH₂Cp)Hf(NMe₂) 2 and (MeNCH₂CH₂Cp)Zr(NMe₂) 2 were both kept at an ampule temperature of 100° C.

### Example I

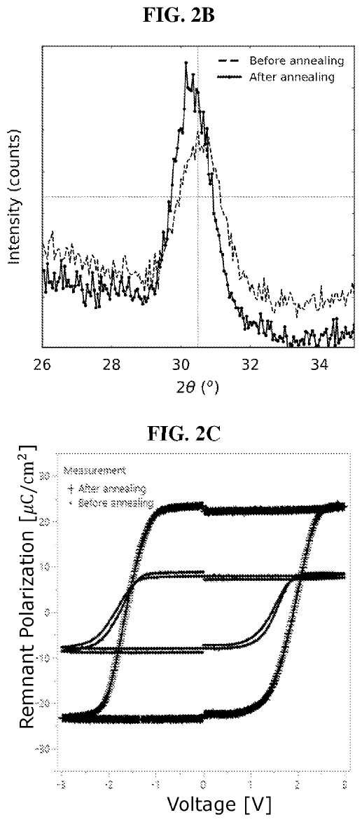

FIGS. 2A-2C show results of optimization process for the bottom electrode. In this example HZO is grown on 50 Å W. FIG. 2A shows intensity before and after post metal annealing, showing the phase transformation of W from a to β phase. α phase is more desirable as a bottom electrode as it is ˜10 times less resistive than β phase.

FIG. 2C illustrates the grazing-incidence XRD pattern for the inherently bottom electrode and the ferroelectric material prepared and deposited on the bottom electrode before and after annealing. As shown in FIG. 2B, the crystalline peaks of the material constituting layer show monoclinic and non-monoclinic components. By fitting the peaks and using the peak areas with the technique described by McBriarty et al., https://onlinelibrary.wiley.com/doi/full/10.1002/pssb.201900285, the calculated monoclinic fraction of the volume of the of the material constituting layer is less than 25%, which is the preferred maximum volume fraction of monoclinic, non-ferroelectric material.

FIG. 2B shows a non-monoclinic peak shift after annealing, indicating the change in HZO crystallinity. FIG. 2C shows improvement of remnant polarization after annealing, indicating the stabilization of desirable ferroelectric phase.

### Example II

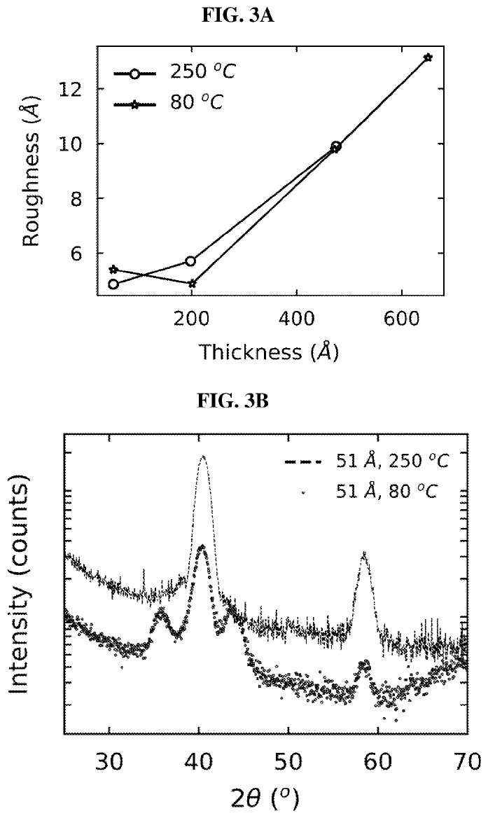

FIGS. 3A-3C show results of an optimization for the bottom electrode. FIG. 3A shows calculated surface roughness of bottom W electrode from X-ray reflectivity, showing an increase in roughness as thickness increases. FIG. 3B shows W grown at high temperature possess higher ratio of a phase. FIG. 3C shows remnant magnetization after annealing of HZO grown on optimized W electrode (100 Å (10 nm) at 250 degrees Celsius) showing a significant improvement.

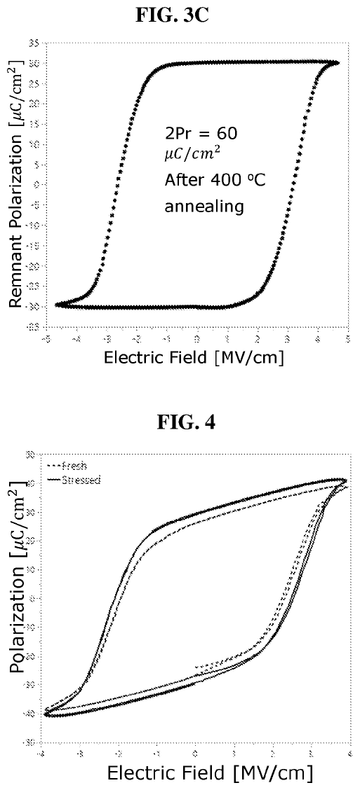

FIG. 4 shows significant ferroelectric polarization for the ferroelectric device at the end of the process integration without the need of wake-up process to activate the ferroelectricity of the film. After electric stress, a minor increase of remanent polarization and shift of coercive field is observed.

For simple metal-FE-metal (MFM) stack fabrication, we deposit W (10 nm) as the bottom electrode (BE) using a PVD process. Then, the HZO film is deposited by ALD. This is followed by capping layer (5 nm W deposited by PVD), a 5-minute PMA from 400 degrees Celsius in N₂ ambient. Circular top electrodes (TE) for electrical testing are TiN 500 Å being defined by a shadow mask and grown by an Endura sputtering chamber at 250 degrees C. followed by SF₆ etch of the capping layer on the field.

In the illustrated embodiment, the bottom electrode comprises tungsten. In other embodiments, the top electrode may comprise any of titanium nitride, molybdenum, ruthenium, platinum, and aluminum. In the illustrated embodiment, 5 or 10 nm thick W is used.

The ferroelectric layer comprises HfₓZr₁₋ₓO₂. In alternative embodiments, the ferroelectric layer may comprise HfO₂ doped with La, Y, Gd, Sr, or combinations thereof.

In the illustrated embodiment a post-metal anneal (PMA) is performed at 400 degrees Celsius for 5 minutes.

One important observation of FIG. 4 is that the ferroelectric behavior is observed even before wake-up cycling with open loop hysteresis. Stress 2.5V 1000 Bipolar Cycles 1 KHz for the frequency.

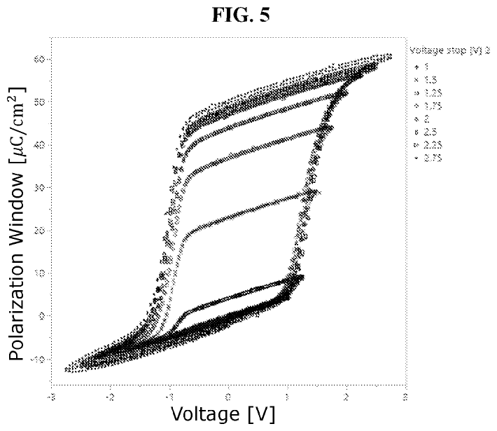

FIG. 5 demonstrates multi-bit programming (>4 states) tuning the remnant polarization of the ferroelectric capacitor. The device has been programmed from +/−1V to +/−2.75V with a programming step of +/−0.25V. The frequency used for all these experiments is 1 KHz.

### Example III

FIG. 6 illustrates the effect of the top electrode on the endurance of the ferroelectric device. The device has been programmed to experience up to 7.2e+6 cumulative cycles of sweeping from 2.25 V to −2.25 V. The pulse width used for all these experiments is 500 ns. FIG. 6 demonstrates the endurance without break-down up to 7.2e+6 cycles for the ferroelectric device with titanium nitride top electrode, compared to an early break-down at 4.1e+6 cycles for the ferroelectric device with the tungsten electrode.

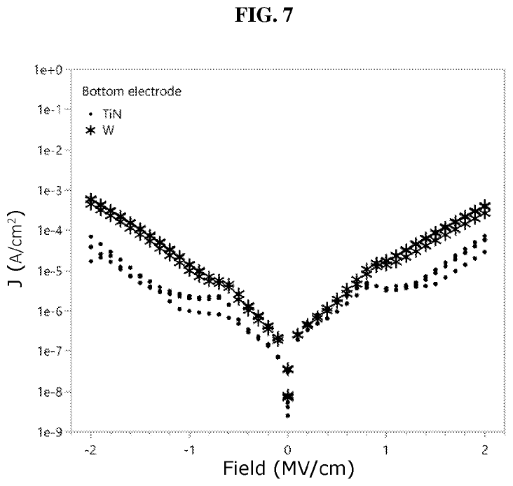

FIG. 7 demonstrates the effect of the bottom electrode on the leakage response of the ferroelectric device. FIG. 7 shows the ferroelectric device with titanium nitride bottom electrode possesses a lower leakage response (current density with unit Ampere/cm²) at 2 V compared to the ferroelectric device with tungsten bottom electrode.

The ferroelectric layer comprises HfₓZr₁₋ₓO₂. In alternative embodiments, the ferroelectric layer may comprise HfO₂ doped with La, Y, Gd, Sr, or combinations thereof.

In the illustrated embodiment, a post-metal anneal (PMA) is performed at 400 degrees Celsius for 5 minutes.

In the illustrated embodiment, the top electrode comprises tungsten or titanium nitride. In other embodiments, the top electrode may comprise any of molybdenum, ruthenium, platinum, and aluminum. In the illustrated embodiment, 5 nm thick top electrode is used.

In the illustrated embodiment, the bottom electrode comprises tungsten or titanium nitride. In other embodiments, the bottom electrode may comprise any of molybdenum, ruthenium, and platinum. In the illustrated embodiment, 5 or 20 nm thick bottom electrode is used.

A further advantage of the instant FTJ system is a lower overall thermal budget. It is important for on-chip back-end-of-the-line (BEOL) compatible memory to be fabricated below 400 degrees Celsius temperature in any of its process steps. Typical HZO films were deposited amorphous due to low temperature ALD process and then it requires high temperature annealing for the FE domains to be activated. The illustrated process utilizes high temperature ALD precursors that allows the films to be highly ferroelectric as deposited. Typically, a preferred deposition temperature is between 300 C-350 C and then 400 C annealing is sufficient to make it highly stable. This makes the process flow BEOL compatible.

A further advantage of the instant FTJ system is faster read/write operation. Since the FTJs depend on tunneling electroresistance, the devices are high resistive compared to other non-volatile memory technologies like ReRAM and PCM in both their low resistance and high resistance states. Although this is desirable for energy dissipation point of view, too high resistance require high voltage to read causing reliability concern and slower pulses causing the read and write unreasonably slow and more prone to noise. Since we do not require any dielectric layers to create asymmetry and the films have high remnant polarization, the stack can be designed to be thin and still have sufficient FE dipole to create a memory window. This makes the illustrated FTJ stack highly scalable, both in terms of the thickness of the ferroelectric material and the area of the device.

It will be apparent to those skilled in the art that various modifications and variations can be made in the disclosed subject matter and specific examples provided herein without departing from the spirit or scope of the disclosed subject matter. Thus, it is intended that the disclosed subject matter, including the descriptions provided by the following examples, covers the modifications and variations of the disclosed subject matter that come within the scope of any claims and their equivalents. Materials and Methods:

The metallocene precursors were or otherwise can be prepared according to U.S. Pat. No. 8,568,530 the contents of which is incorporated herein in its entirety.

After deposition, the films were characterized by grazing-incidence XRD on a Bruker D8 Discover diffractometer using a monochromated Cu X-ray tube (Cu Kα, λ=1.5418 Å). The incident beam angle was fixed at 0.7°, and XRD patterns were collected over the range 2θ 20°-40° in 0.05° steps using a position-sensitive detector. For ferroelectric testing, TIN top contacts (50 nm thick) were deposited by PVD at 250° C. (i.e., at a non-annealing temperature below the temperature for ALD growth) in an Applied Materials Endura PVD tool. The circular contacts (0.203 mm diameter; 0.032 mm² area) were defined by a shadow mask. Polarization curves were collected using a Radiance Precision II ferroelectric tester and a Cascade probe station. Polarization field data were collected with a bipolar triangular waveform (5 kHz, −3V to 3V in 0.25V steps) before and after applying a wake-up stress of +3 V at 1 KHz for 1 s. As shown in FIG. 3C, the as-deposited layer has remanent polarization (Pr) of greater than 30 μC/cm², or a total loop opening 2Pr of greater than 60 μC/cm², when measured using triangular bipolar waveform with a maximum applied field of approximately 3.8 MV/cm. Not bound by theory, it is expected the as-deposited layer may have remanent polarization (Pr) of 20 μC/cm² or greater, or 30 μC/cm² or greater, or 40 μC/cm² or greater or a total loop opening 2Pr of 50 μC/cm² or greater, or 60 μC/cm² or greater, or 70 μC/cm² or greater when measured using triangular bipolar waveform with a maximum applied field of approximately 3.8 MV/cm.

Although the invention has been described and illustrated with a certain degree of particularity, it is understood that the disclosure has been made only by way of example, and that numerous changes in the conditions and order of steps can be resorted to by those skilled in the art without departing from the spirit and scope of the invention.

What is claimed is:

1. A ferroelectric device comprising:
a substrate;
a first electrode and a second electrode, wherein the first electrode is disposed on the substrate;
a thin film comprising crystalline material disposed between the first electrode and the second electrode, the crystalline material comprising hafnium oxide and zirconium oxide, wherein the crystalline material exhibits ferroelectric behavior as deposited; and
wherein the first electrode comprises tungsten, wherein greater than 50% of the total volume of the first electrode is in α phase, and the thin film having a remnant polarization of greater than about 50 μC/cm².

2. The ferroelectric device of claim 1, wherein the thin film is capable of exhibiting ferroelectric activity without a wakeup period.

3. The ferroelectric device of claim 1, wherein the second electrode comprises titanium nitride, tungsten, molybdenum, or combinations thereof.

4. The ferroelectric device of claim 1, wherein the first electrode has a thickness of between about 4 nm and about 50 nm.

5. (canceled)

6. The ferroelectric device of claim 1, wherein the crystalline material comprises a hafnium oxide to zirconium oxide ratio of between about 1:3 and about 3:1.

7. (canceled)

8. (canceled)

9. The ferroelectric device of claim 1, wherein the crystalline material is derived from one or more metallocene precursor having Formula I: 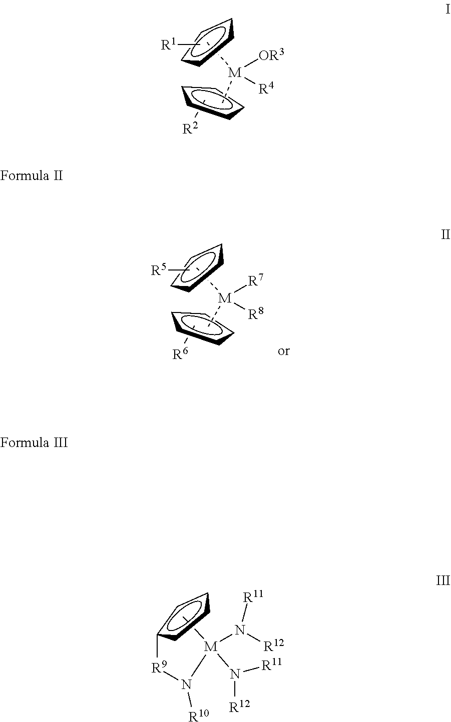
wherein (i) M is selected from Zr and Hf, (ii) R¹, R², R³, R⁴, R⁵, R⁶, R⁷ and R⁸ are each a methyl group, (iii) R⁹ is a C₁-C₄ group selected from —CH₂CH₂—, —CH₂CH₂CH₂—, —CH(Me)CH₂—, —CH₂CH(Me)-, —CH₂CH₂CH₂—, —CHMeCH₂CH₂—, and (iv) R¹⁰, R¹¹, and R¹² are each independently a C₁-C₆ linear alkyl.

10. The ferroelectric device of claim 1, wherein there is hysteresis and remanent polarization in a polarization-electric field measurement.

11. The ferroelectric device of claim 1, wherein the film has a thickness of approximately 0.2 nm to approximately 10 nm.

12. A method of creating a ferroelectric device comprising:
(i) providing a substrate;
(ii) depositing a first electrode onto the substrate, the first electrode comprising tungsten;
(iii) depositing a ferroelectric layer onto the first electrode at a deposition temperature, the ferroelectric layer comprising zirconium and hafnium;
(iv) depositing a second electrode onto the ferroelectric layer; and
(v) annealing the first electrode at a temperature of 400 degrees Celsius or less;
wherein greater than 50% of the total volume of the first electrode is in a phase.

13. The method of claim 12, wherein an annealing step is conducted at a temperature greater than about 350 degrees Celsius.

14. The method of claim 12, wherein no process steps take place at a temperature greater than about 400 degrees Celsius.

15. The method of claim 12, wherein the ferroelectric layer comprises hafnium zirconium oxide.

16. (canceled)

17. The method of claim 12, wherein the first electrode has a thickness of between about 4 nm and about 50 nm.

18. A method of creating a ferroelectric device comprising:
(i) providing a substrate;
(ii) depositing a first electrode onto the substrate at a first temperature, wherein the first electrode comprises tungsten;
(iii) depositing a ferroelectric layer onto the first electrode at a second temperature; and
(iv) depositing a second electrode onto the ferroelectric layer;
(v) conducting an annealing step at a third temperature;
wherein the first temperature, the second temperature, and the third temperature are less than or equal to 400 degrees Celsius, and wherein greater than 50% of the total volume of the first electrode is in a phase.

19. The method of claim 18, wherein the first temperature is between about 15 degrees Celsius and about 400 degrees Celsius.

20. The method of claim 18, wherein a thickness of the first electrode is between about 4 nm and about 50 nm.

21. The method of claim 18, wherein in the annealing step, the third temperature is greater than or equal to about 350 degrees Celsius and less than or equal to 400 degrees Celsius.

22. The method of claim 18, wherein no process steps take place at a temperature greater than about 400 degrees Celsius.

23. The method of claim 18,
wherein the second electrode comprises titanium nitride, tungsten, molybdenum, or combinations thereof.

24. (canceled)

25. (canceled)

26. (canceled)

27. (canceled)

28. (canceled)

29. (canceled)

30. (canceled)
